(19) United States
(12) Patent Application Publication
(10) Pub. No.: US 2015/0233731 A1
(43) Pub. Date: Aug. 20, 2015

(54) METHOD AND APPARATUS FOR MONITORING A CONDITION OF A METER

(71) Applicant: Landis & Gyr Pty Ltd., Alexandria, New South Wales (AU)

(72) Inventors: Keith Torpy, Alexandria (AU); Marc Circosta, Annandale (AU); Marcelo DeMarco, Alexandria (AU); Ian Davis, Alexandria (AU); Paul Collins, Alexandria (AU)

(21) Appl. No.: 14/408,905

(22) PCT Filed: Jul. 6, 2012
(86) PCT No.: PCT/AU2012/000821

§ 371 Date: May 7, 2015

(30) Foreign Application Priority Data
Jul. 8, 2011 (AU) 2011902724
Aug. 16, 2011 (AU) 2011101045

(51) Int. Cl. G01D 3/036; H02B 1/03; H02H 5/04; G01K 3/00; G01R 35/04

(52) U.S. Cl. CPC G01D 3/0365; G01K 3/005; G01R 35/04; H02H 5/047; H02B 1/03

(57) ABSTRACT

A method and apparatus for monitoring the condition of a utility meter by obtaining a temperature value associated with the meter, determining whether the temperature value crosses a threshold, triggering an action if the threshold value is crossed. In another form the temperature can be used as a fault parameter to determine the condition of a utility meter.

### FIELD OF THE INVENTION

The present invention relates to a method and apparatus for monitoring a condition associated with a meter, particularly, but not exclusively, an electric meter.

### BACKGROUND OF THE INVENTION

Utility meters for monitoring the consumption of resources, such as electricity or gas, are well known. Such meters are used in domestic and industrial environments. It is usually a regulatory requirement for most countries that meters be installed for monitoring resource consumption at all premises.

An electricity meter generally has one or more active lines coming from the main power lines, one or more neutral lines and one or more load lines going to the premises.

An industrial electric meter generally has multiple active lines coming from the street. An industrial electric meter may be adapted for large current usage where there are large voltage and current uses in the industrial environment.

A number of fault conditions can occur within any of the lines, within the meter and within the premises. The term premises in this specification refers to a domestic premises or an industrial premises.

It is known to monitor currents and/or voltages associated with an electricity meter in order to determine faults or any hazardous conditions associated with the meter.

High temperatures can often occur within the metering box due to the presence of live electrical wires within the metering box. Temperature in the meter may also increase if the internal circuitry of the meter has a fault or has been damaged. Increased temperature in the meter can result in errors in reading current usage or voltage usage. Large temperatures can also damage circuitry within the meter such as the microcontroller or sensors or other components of the meter. Furthermore large or increased temperatures can introduce errors into the metering and measuring cycles.

### SUMMARY OF INVENTION

In accordance with a first aspect, the present invention provides a method of temperature in a meter comprising the steps of:

receiving one or more temperature signals from which a temperature value can be derived;

determining whether the signal exceeds one or more threshold values; and if so

providing a trigger signal arranged to trigger an action.

In accordance with a second aspect, the present invention provides an apparatus for monitoring temperature in a meter comprising:

at least one or more sensors arranged to collect a temperature signal;

a processor arranged to receive one or more temperature signals from the sensor, determine whether the signal exceeds one or more thresholds, send a signal to an action device to perform an action; and

at least one action device arranged to receive a trigger signal from the processor and execute an action.

In an embodiment, the temperature value is an instantaneous temperature value.

In another embodiment, the temperature value is a temperature gradient.

The temperature gradient may be the rate of change of temperature over time. Alternatively, the temperature gradient may be the temperature profile along or across any area of the meter (i.e. the temperature profile may be a temperature distribution across an area of the meter).

In an embodiment, the threshold may relate to an instantaneous temperature threshold.

In another embodiment, the temperature threshold may relate to a temperature gradient threshold.

In a further embodiment, the threshold may relate to a temperature profile threshold.

The threshold or thresholds can be a minimum value or maximum value or any other value that can be used to monitor the condition of a meter. The threshold may also relate to a particular condition of a meter.

In accordance with a third aspect, the present invention provides a method of monitoring the condition of a utility meter comprising the steps of:

obtaining a temperature value associated with the meter;

determining whether the temperature value crosses a threshold value; and

triggering an action if the threshold value is crossed;

wherein the temperature value is a temperature gradient.

The applicants have appreciated that temperature associated with a meter can be used to determine a condition of the meter or associated with the meter. They therefore propose to utilize temperature as a fault parameter. Alarms can be given and/or other actions taken if the temperature value indicates a condition such as a fault condition.

Temperature can be used on its own as a fault parameter. In an embodiment temperature can be used in combination or separately with current and/or voltage to determine fault conditions.

In an embodiment, the temperature gradient is a rate of change of temperature over time.

In an embodiment, the temperature value may be a temperature gradient, for example rate of change of temperature with time. A steep temperature rise in or about the meter may indicate a fault condition, for example.

In an embodiment the temperature value may be a temperature profile, the temperature profile being the temperature distribution across different locations of or about the meter.

In an embodiment an action may be any one of:

an alarm event;

actuating a switch, such as, for example, a load control relay or a mains circuit breaker or any other switch. The switch may control current, such as current to or in a premises, for example; and

transmitting a message to an external server or external administrator regarding a fault condition.

An advantage of using temperature to determine the condition of a meter, in accordance with an embodiment of the present invention, is that temperature provides an alternative or additional fault parameter to presently available fault parameters, such as current and voltage.

In accordance with a fourth aspect the present invention provides an apparatus for monitoring the condition of a utility meter, comprising:

a processor arranged to determine a temperature value associated with the meter;

the processor further arranged to determine whether the temperature value crosses a threshold value;

the processor arranged to trigger an action if a threshold value is crossed; and

wherein the temperature value is a temperature gradient.

In an embodiment the apparatus may comprise one or more sensors arranged to detect temperature.

In an embodiment the apparatus further comprises an action device that performs an action.

In an embodiment the action device can be any one of:

an alarm;

a load control relay;

a mains circuit breaker; and

a communications arrangement arranged to communicate with an external server.

The action device may comprise any type of switch which may control electric power (current and/or voltage) to/from the meter or to/from a premises associated with the meter.

In another embodiment the apparatus may comprise any one or more of:
(a) a load control relay;
(b) a mains circuit breaker;
(c) an audible alarm;
(d) a visual alarm; and
(e) a communications arrangement arranged to communicate a message or alarm event to an external server;

wherein the action is triggering any one or more of the features (a) to (e).

In accordance with a fifth aspect the present invention provides a method of monitoring the condition of a utility meter, comprising the step of utilizing temperature as a fault parameter.

In accordance with a, sixth aspect, the present invention provides an apparatus for monitoring the condition of a utility meter, comprising a processor arranged to utilize temperature to indicate a meter fault.

In accordance with a seventh aspect, the present invention provides an apparatus for monitoring temperature in a meter comprising:

at least one or more sensors arranged to collect a temperature signal;

a processor arranged to receive one or more temperature signals from the sensor(s) and determine a temperature value from the signals;

the processor further arranged to determine whether the temperature value crosses one or more thresholds and to cause a trigger signal to be sent to an action device to perform an action; and

at least one action device arranged to receive a trigger signal from the processor and execute an action.

In accordance with an eighth aspect, the present invention provides a computer program, comprising instructions for controlling a computer to implement a method in accordance with a first or third or fifth aspect of the invention.

In accordance with a ninth aspect, the present invention provides a computer readable medium providing a computer program in accordance with the eighth aspect of the invention.

In accordance with a tenth aspect, the present invention provides a data signal comprising a computer program in accordance with the ninth aspect of the invention.

### BRIEF DESCRIPTION OF THE FIGURES

Features and advantages of the present invention will become apparent from the following description of embodiments thereof, by way of example only, with reference to the accompanying drawings, in which;

FIG. 1 shows a view of an electric meter, the view showing the external features of the meter and the interaction of the components of the meter;

FIG. 2 shows a schematic of an apparatus for monitoring a condition of a meter using temperature, in accordance with an embodiment of the present invention;

FIG. 3 is a flow diagram illustrating a method for monitoring a condition of a meter using temperature, in accordance with an embodiment of the present invention;

FIG. 4 is a flow diagram illustrating another method for monitoring a condition of a meter using temperature, in accordance with an embodiment of the present invention;

FIG. 5 is a flow diagram illustrating a further method for monitoring a condition of a meter using temperature, in accordance with an embodiment of the present invention; and

FIG. 6 is a flow diagram illustrating a further method for monitoring a condition of a meter using temperature, in accordance with an embodiment of the present invention.

### DETAILED DESCRIPTION OF EMBODIMENTS OF THE INVENTION

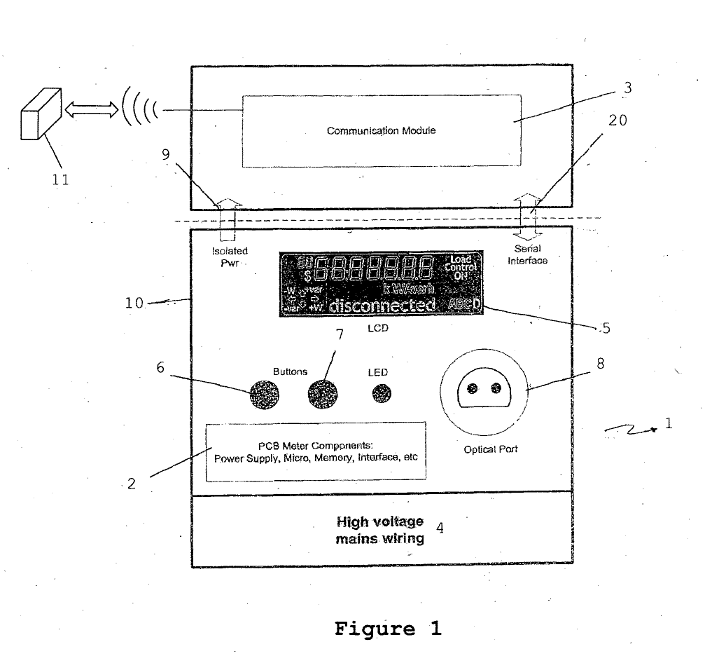

FIG. 1 shows an electricity meter. The meter 1 comprises meter circuitry 2 and a communications module 3. The meter circuitry is arranged to monitor and be connected to the mains supply. The meter is arranged to determine and measure the electricity consumption by a premises, which may be domestic or industrial or other premises. In this embodiment high voltage terminals 4 are provided for connecting the mains voltage to the meter circuitry 2 such that the meter circuitry can monitor electricity flow and/or consumption.

The communications module 3 is electrically isolated from the mains supply and high voltage wiring 4. In one embodiment the communication module 3 may be the module or communication apparatus described in Australian patent application AU 2009902065. In another form the meter 1 may be the meter described in Australian patent application AU 2009902065, which is incorporated herein by reference.

In one embodiment, as shown in FIG. 1, the meter circuitry may be mounted on a PCB and comprises a power supply, a microprocessor for controlling the meter, memory and an interface to a display 5. The meter also comprises a user interface (buttons 6, 7 and an optical port 8). A serial RS232 interface is provided for communications between the communications module and the meter circuitry. A power supply 9 supplies power to the communications module 3. The meter 1 has a casing 10 which houses the above mentioned components. In one form the casing 10 may encompass the communication module 3. In another embodiment the communication module 3 may be outside the casing 10 but still in communication with the meter 1.

In one embodiment the communication module is arranged to communicate with an external management service 11. The management service 11 may be in the form of a computing arrangement, such as one or more servers that receive data from a plurality of meters. The management service allows an organisation to manage and monitor the operation of all meters served by the management service.

The communication module is further arranged to communicate with internal components in the meter such as the microprocessor or with the display 5. In one form a serial interface 20 may be provided for communication between the communication module 3 and the meter 1 or meter components. The communications module 3 receives or can read any of the metering data such as energy registers, interval data, event logs etc from the meter 1, as well as sending commands to perform tasks such as activating relays or circuit breakers, setting time, clearing registers etc. Any suitable serial link can be used for communication between the communication module and the meter or the processor. An example of a suitable serial link or communication link is an RS 232 communication link. A RS 232 communication link to the meter is via a standard ANSI C12.18 protocol or any other suitable communication protocol. The communications module 3 can communicate information about the meter to the external server 9 for monitoring. The external server 9 is arranged to communicate various instructions to the meter 1 via the communications module 3.

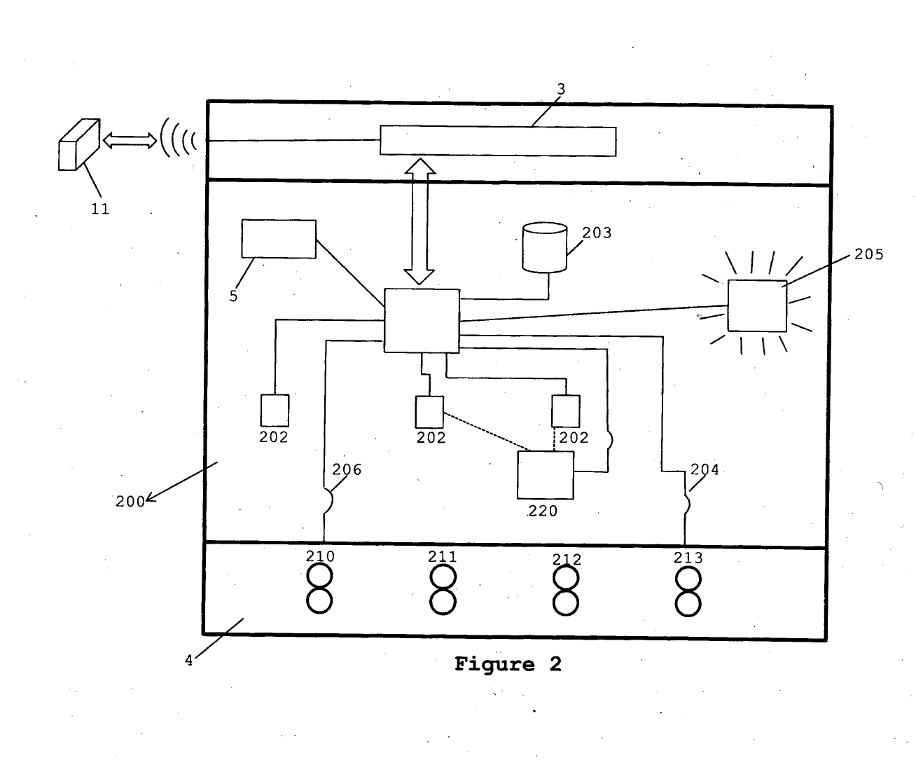

FIG. 2 shows an apparatus for monitoring temperature in a meter 1, in accordance with an embodiment of the present invention. This embodiment is arranged to monitor temperature and determine whether the monitored temperature may indicate that action needs to be taken, such as switching off power to the premises, or causing an alarm, or other action. The apparatus is generally designated by reference numeral 200. The apparatus includes a processor 201 and at least one sensor 202 to collect temperature signals from which a temperature value can be obtained. The apparatus may further comprise a power source 220 that supplies power to the internal components of the meter 1 to operate the meter. The power supply 220 may be the same as the power supply described with respect to the metering circuitry.

The sensors 202 may be any suitable sensors for measuring temperature. In one example a MMI3 ASIC sensor by Landis+Gyr can be used to measure temperature. In another form the sensor 202 may be part of the sensors or PCB meter components used to determine voltage or power consumption, as described earlier. The sensor may be formed on the PCB used for the metering circuitry or may be formed as one unit with the metering circuitry 2.

In one form there may be a plurality of sensors 202 arranged within the meter 1. The sensors can be arranged in any suitable arrangement to determine the temperature in the meter 1. The sensors 202 may be positioned on the casing 10 of the meter to determine the temperature in the meter. In other forms one sensor 202 may be positioned on the casing and the other sensors may be distributed around other locations within the meter 1 to monitor the temperature in the meter 1. The sensors 202 can be distributed in any suitable locations in the meter 1 to determine the temperature or detect temperature within the meter 1. In a further alternative embodiment the sensors may be part of a modular sensor module that can be fitted to the meter. The module (not shown) may be removably coupled to the meter.

The processor 201 can be any suitable processor. The processor is arranged to receive temperature signals from at least one sensor 202 and derive a temperature value and perform other tasks. The processor is arranged to receive one or more temperature signals, derive a temperature value from the temperature signals; determine whether the signal exceeds one or more threshold values and if so providing a trigger signal arranged to trigger an action. In one form the processor 201 may be a MI6C processor as manufactured by Mitsubishi or Reneassas. In another form the processor 201 may be the same processor described with respect to the metering circuitry 2.

The apparatus 200 further comprises a storage device 203. The storage device can be any suitable storage device such as memory device, ROM, RAM, a hard disk, flash memory or any other suitable storage device. The storage device 203 is in communication with the processor and is arranged to receive data and store data from the processor 201. The storage device 203 is further arranged to allow the processor 201 to extract stored data from the storage device 203.

FIG. 2 shows one embodiment of the mains wiring 4. As can be seen from the figure the mains wiring may comprise an active wire 210, two neutral wires 211, 212 and a load wire 213. In other forms there may be multiple load wires 213. The active 210 is the power line from the street mains. The load wire 213 is the power line supplying power to the premises.

The apparatus 200 comprises at least one action device. The action device may be a load control breaker 204, a mains breaker 206 or an alarm device 205. In one form the apparatus comprises at least one load control breaker 204, at least one mains breaker and at least one alarm device 205. In other forms the apparatus may include only some of these active devices or just one action device. In further alternate forms the apparatus may comprise a plurality of each action device.

In one form the load control breaker 204 is adapted to break the circuit of at least one load wire to reduce the current drawn by the premises. In one form the mains breaker is adapted to break power to the premises by creating a break in the active line 210. The mains breaker 206 is adapted to cut power to the premises. The load control breakers 204 and the mains breaker 206 are within the meter.

In another form the mains breaker 206 may disconnect power from the internal power supply 220 to the meter causing the meter 1 to shut down. This form is not shown. The breakers 204 and 206 may any suitable circuit breakers such as relays or fuses or any other suitable circuit breaker. The circuit breakers 204, 206 are activated by a signal from the processor 201 if the temperature value crosses a threshold. The apparatus 200 may comprise an alarm device 205 such as a buzzer or other audible alarm that may be activated by the processer if the temperature value crosses a threshold.

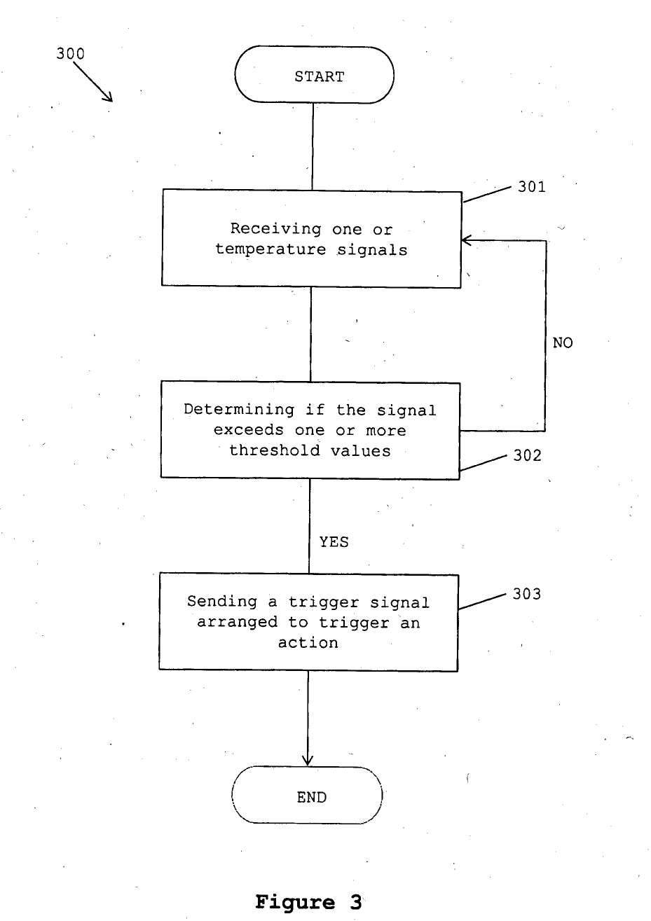

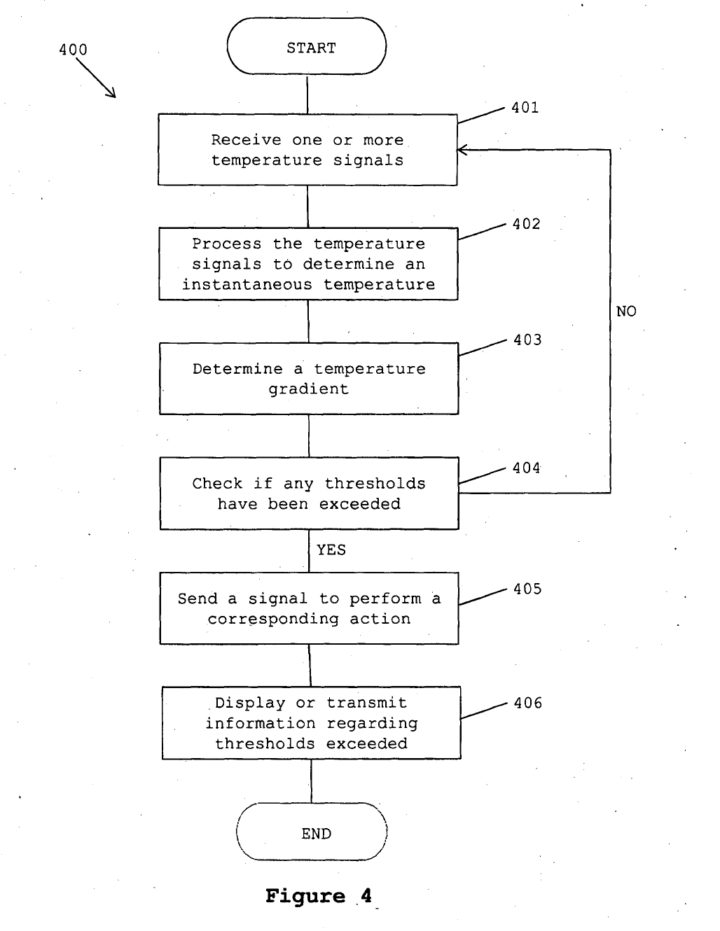

A method for monitoring temperature within or about a meter will be described with respect to FIGS. 3 and 4. The general method 300, shown in FIG. 3, as implemented by the processor 201 comprises the steps of receiving one or more temperature signals from which a temperature value can be derived, at step 301. At step 302, determining whether the signal exceeds one or more threshold values, and if so, sending a trigger signal arranged to trigger an action, at step 303.

Another method as implemented by the processor 201 is shown in FIG. 4. The method 400 comprises the steps of receiving one or more temperature signals, at step 401. Processing the temperature signals to determine an instantaneous temperature value at step 402. At step 403 the processor determines a temperature gradient value. At step 404 the processor checks which thresholds have been exceeded by the instantaneous temperature and temperature gradient values. If one or more thresholds has been exceed the processor 201 sends a trigger signal to perform a corresponding action, at step 405. Each threshold has at least one action device which is triggered by the trigger signal. Finally at step 406 the processor sends a signal to the communication module 3 to transmit a signal to an external server 9 or an administrator regarding which thresholds have been breached or exceeded. The processor may also send a signal to display 5 to display which thresholds have been exceeded.

The temperature gradient may be temperature over time. A rapid increase in temperature may indicate a fault condition. In this embodiment (FIG. 4), this is used together with the instantaneous temperature value (actual temperature at the time) to determine what actions should be taken.

The method steps are iterated periodically. In other words, the method samples or receives temperature signals at set time intervals, for example every 500 ms. The sensors 201 may be arranged to sample values or take measurements at a predetermined time interval, for example every 200 ms or 500 ms. In another form the sensors 201 may transmit the signal value at a predetermined time interval for example every 500 ms. The method as per FIG. 3 or 4 is iterated at regular time periods. For example the processor runs the method every 2 minutes or 3 minutes or at any other regular time period. The method is iterated, at every time period in order to constantly monitor the temperature in the meter and to constantly monitor for any threshold values being exceeded.

As stated in step 402 the processor is arranged to determine the instantaneous temperature value from the temperature signal. The processor 201 can undertake this steps using any suitable mathematical formula. In one example the processor 201 may be programmed with sensor calibration data or from the operation data of the sensor, in order to determine an instantaneous temperature reading from a temperature signal.

At step 403 the processor determines a temperature gradient value. This can be performed for the sampling period described above or for any other predetermined period. The processor receives temperature signals at predetermined time periods. This time period may correspond to the sampling period. In another form the predetermined time period is greater than the sampling period. The processor may have associated with it a buffer to hold signals or signal values from the sensors 202. At the predetermined time period the processor 201 receives the signal value and derives a temperature gradient using the predetermined time period.

The temperature gradient value is determined as rate of change of temperature. The period of change may be set by the user when the meter is installed or may be programmed by an external source 11 via the communications module. The temperature gradient may be calculated by determining the instantaneous temperature value at the start of the time period, determining the instantaneous temperature value at the end of the time period, calculating the difference between the two temperature values and dividing by the time period to determine the temperature gradient value. In one example the gradient may be determined as degrees Celsius per minute. The time period as described earlier may refer to the sampling period or another predetermined time period the processor receives the signals and derives a temperature gradient.

The processor checks whether a threshold has been breached or exceeded at step 404. The processor checks a plurality of thresholds. The threshold, information may be stored in storage device 203 or in memory associated with the metering circuitry. The thresholds may be changed by a person. In one form a user may change the thresholds by using the optical port 8 and uploading threshold data. In another form the user may use buttons 6 and 7 to manually program threshold data. In a further form an external manager may program new or change threshold values by sending signals to the processor 201 via the communication module 3. The manager is an authorised administrator or authorised user with sufficient privileges, to access the meters in a meter network.

As stated previously a plurality of thresholds may be stored. At least one minimum threshold, at least one maximum threshold and at least one detection threshold may be stored. Each type of threshold is associated with at least one corresponding trigger value, such that when the threshold value is exceeded the corresponding trigger value is provided by the processor 201. Once the trigger value is provided a corresponding action takes place. Each threshold being exceeded results in a different action being triggered. The actions will be described later. The following is an explanation of some example thresholds.

The minimum threshold is a minimum temperature value that indicates the temperature in the meter is increasing to a potentially dangerous level. The minimum threshold can be set at a different value depending on the type of meter. In one example the minimum threshold may be 55° C. If the temperature in the meter exceeds this value, then an action is triggered. In one form the minimum threshold is determined based on the instantaneous temperature in the meter. For example, if the instantaneous temperature in the meter rises above 55° C. then an action is triggered.

The detection threshold is a related to the rate of change of temperature within the meter. The rate of change (i.e. the temperature gradient) exceeds the threshold rate of change (i.e. threshold gradient), indicates the temperature is rising at a dangerous rate and there may be a fault in the meter or meter components. The detection threshold in one example may be 5° C./min. If the temperature gradient within the meter is above this value an action is triggered.

The maximum threshold is related to instantaneous temperature. The maximum threshold indicates the maximum tolerable limit of temperature within the meter. If the instantaneous temperature value exceeds the maximum threshold, this is an indication that the meter may fail and stop working, or the meter will be damaged. In one example the maximum threshold may be 95° C. If the instantaneous temperature in the meter rises to above 95 degrees Celsius then an action is triggered.

As previously mentioned each threshold has its own triggered action associated with it. The actions may be any one of triggering an alarm event such as a buzzer 205 or activating at least one circuit breaker 204 that shuts off power to part of a house or activating a mains circuit breaker 206 which shuts off power to the house. Another example of an action may be to shut off power to the meter only by disconnecting the power supply 220. A further example of an action may be to transmit an alarm event to an external manager 9 via the communications module 3.

In one embodiment the processor checks if the instantaneous temperature has exceeded the minimum threshold. If so, then an alarm event is triggered in response. This alarm event may be the activation of a buzzer 205 to let a user know. Alternatively, an alarm signal may be transmitted to an external manager 9 via the communications module. If the minimum threshold has not been exceeded, this indicates the meter is operating at the correct temperature.

Following the checking of the minimum threshold, the processor checks if the temperature gradient has exceeded the detection threshold. In one embodiment this step or check may only be performed if the minimum threshold has been exceeded. If the temperature gradient exceeds the detection threshold a trigger is sent to activate at least one load control breaker 204. The load control breaker 204 breaks the circuit to at least one load line 213. Breaking the circuit to one load line, such as the line to a water heater, may reduce the current drawn, and may result in a steadying of the temperature in the meter. The processor may be able to determine which load line is causing the temperature increase and activate the load control breaker to isolate the load line that is causing the temperature increase. In another form the load control breaker will break the circuit to the house and stop supplying power to the house.

If the minimum threshold and detection threshold are exceeded, the processor checks if the maximum threshold has been exceeded. If the instantaneous temperature in the meter exceeds the maximum threshold a trigger is sent to activate a mains breaker 206. In one form the mains breaker 206 breaks the circuit of the active line, isolating the meter and house. In another form the mains breaker 206 may break the circuit between the processor and power supply 220.

In a further form the information relating to thresholds being exceeded can be displayed on the display 5. The thresholds being exceeded may also be transmitted to an external server 11 by the communications module. The methods described above maybe implemented as software instructions by the processor 201. The methods described above may be implemented by a computing program arranged to be executed on the processor 201.

In a further form the processor 201 may implement either the method shown in FIG. 3 or FIG. 4 and only determine the temperature gradient. The processor 201 may then check whether the temperature gradient has exceeded a trigger value associated with a threshold value. If the gradient has exceeded a predetermined threshold a trigger signal is generated by the processor. The trigger signal activates an action device as described above. In this form there may be a plurality of threshold values relating to different rates. For example a “low” threshold may relate to a temperature increase of 2° C. per minute, a high threshold, may relate to a temperature increase of 10° per minute and so on. There may be various other pre-determined thresholds that relate to different rates of temperature increase.

Each threshold may have its own triggered action. The actions may be any suitable action from alerting a user or external administrator of an increased temperature to taking corrective action to switch off power to either the electric meter or the premises.

Temperature gradients are used because often it is hard to determine the existing calibration for sensors within an installed electric meter. Temperature gradient is a more stable measurement that can be used to determine the operating conditions within an electric meter. In meters that are installed there is no way of determining whether the sensor is calibrated correctly or not. Often after excessive use, the sensor calibration can change and the sensor does not produce an exact signal as it did when calibrated. Quite often sensor signals have an error associated with them also. The error may be introduced as part of the sensor design or may be due to excessive use or may be due to any other reason. Utilising a temperature gradient as a measuring unit overcomes any errors that may be introduced into the sensor signals. An increased temperature gradient means the meter is heating up at a faster rate. If the gradient exceeds a threshold means the meter is not functioning correctly and a corrective action must be taken.

In a further embodiment a plurality of sensors 202 can be used at different locations within or about the meter 1. The processor 201 may be arranged to derive a temperature profile from the temperature signals from the sensors 202. The temperature profile is the temperature within the meter at different parts within or around the meter. The temperature profile is related to temperature across the meter space.

The processor 201 compares the temperature profile with at least one profile threshold. The processor 201 or memory 203 of the threshold relates to a safe temperature profile within the meter 1. The profiles relate to different temperatures at different points in the meter. Certain parts of the meter (either inside or outside) are warmer than other parts of the meter. The processor determines if the temperature profile within the meter or about the meter exceeds at least one or more profile thresholds. If the profile threshold is exceeded, the processor provides a trigger signal arranged to trigger an action within the meter. The action can be any suitable action such as activating a load control relay.

Any one or more thresholds can be used to determine if there is a fault in either the meter or a fault at some point of the meter. For example, loose connections at the terminals, or incorrect wiring, incorrect installation or added heat transfer at terminals, are examples of some faults. These faults can cause an abnormal temperature rise within the meter 1. Various faults can cause increased temperatures at some point in or around the meter. For example, loose connections or incorrect wiring can cause increased temperature at the terminals or around the terminals. The increased temperature changes the temperature profile in or around the meter 1.

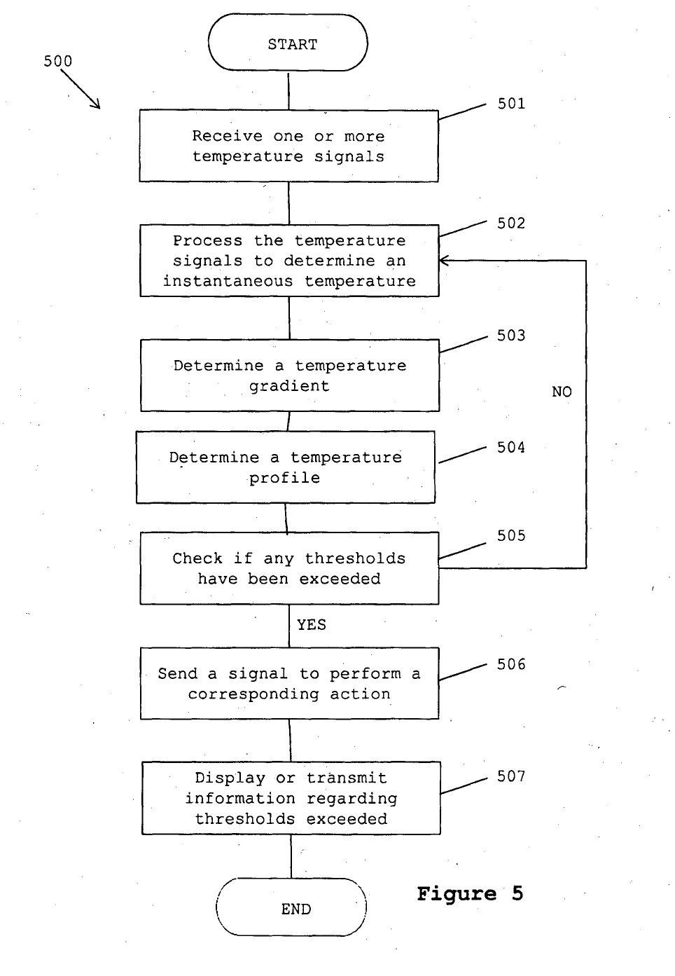

A further embodiment of the method of monitoring temperature in or around an electric meter is shown in FIG. 5. The method includes the steps of receiving one or more temperature signals at step 501, processing the signals to determine an instantaneous temperature at step 502, determining a temperature gradient at step 503, determining a temperature profile at step 504, checking whether any thresholds have been exceeded at step 505, if yes then sending a signal to perform an action at step 506 and then displaying or transmitting the information regarding which thresholds were exceeded to an external administrator or any other person.

Step 504 involves checking the measured or calculated temperature profile with one or more profile thresholds. The profile thresholds relate to safe temperature profiles within or about or around the meter. The profile thresholds may be stored in the storage device or may be externally programmed or sent to the processor by an external administrator 11. If the temperature profile within or around the meter 1 is greater than or different to the safe profile thresholds, a trigger signal is sent to trigger an action. The processor may include a plurality of profile thresholds. Some profile thresholds may relate to hazardous conditions within or about the meter. At least one of the profile thresholds relates to a dangerous temperature threshold within the meter. In one embodiment if a maximal temperature threshold is exceeded, the mains breaker 206 is tripped to switch off power to the house. In another embodiment if a profile threshold is exceeded, one or more load control relays 204 may be tripped or an alarm may be sounded or a message can be sent to an external administrator 11.

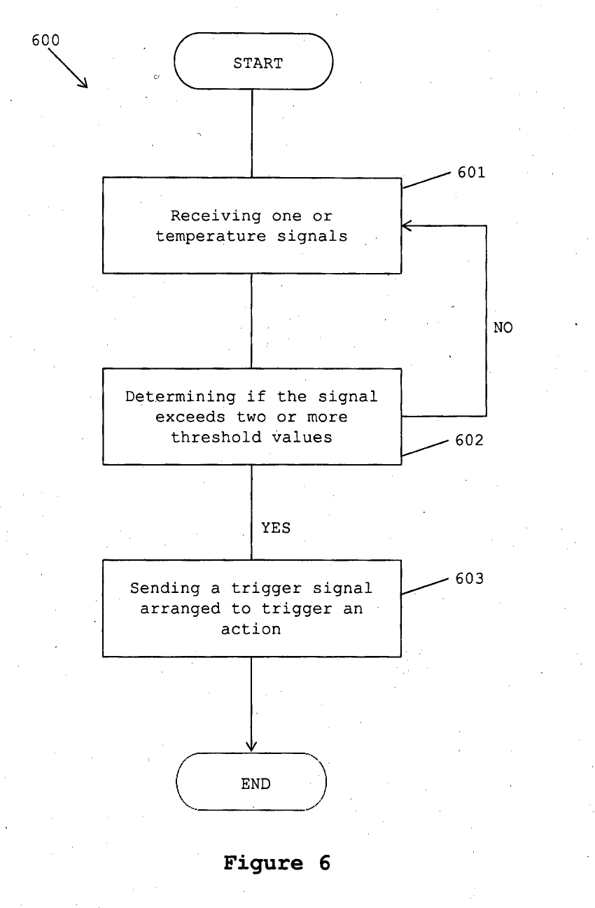

FIG. 6 shows a further embodiment of a method of monitoring temperature in or about a meter. The method comprises the steps of receiving one or more temperature signals from one or more temperature sensors at step 601. Step 602 involves determining whether the one or more signals has exceeded two or more thresholds. If yes, then at step 603 a trigger signal is sent, the trigger signal being arranged to trigger an action. The thresholds defined at step 602 may be any of the thresholds described earlier. The method in FIG. 6 may include the additional steps of processing the temperature signals and checking various thresholds similar to steps 402 to 404 or 502 to 505. Once the signals are checked against the thresholds, corresponding actions are triggered.

The method described with respect to FIG. 6 includes the step of checking whether two or more thresholds have been exceeded and only then triggering an action. This is advantageous because the method allows for greater confidence before triggering an action. Actions such as activating load control relays 204 or the mains breaker 206 results in power to either a house or an industrial premises, being switched off. In order to ensure some amount of certainty or confidence before switching off power or activating an alarm or sending an alarm signal, the processor 201 checks whether at least two thresholds are exceeded.

In a further embodiment the thresholds may be hard coded into the processor and stored on the storage device 203. In a further embodiment the external server 11 or the external administrator can dynamically update the thresholds. The external administrator 11 can communicate thresholds to the processor via the communications module 3. The thresholds can be constantly, changed or updated during the operation of the meter 1. The thresholds, may be changed based on a number of different parameters, for example seasonal variation, differing ambient temperatures or any other parameter. The thresholds may also be changed due to the measured and stored data or statistical information derived from the stored data, (this will be described later). In a further embodiment the thresholds can be modified using the optical port 8 on the meter. The new thresholds can be loaded onto the storage device 203 via the optical port 8.

Ambient temperature can affect the temperature readings from the sensors 202. Ambient temperature can also affect the temperature within or about the meter 1. The thresholds can be varied to account for the effects of ambient temperature. The meter may comprise a further sensor module (not shown) to measure ambient temperature. The measure ambient temperature may be stored in the storage device 203. The processor 201 may be adapted to modify the thresholds based on the measured ambient temperature values. In a further embodiment the measured ambient temperature values may be transmitted to an external administrator 11. The external administrator 11 may transmit an updated set or an updated threshold to account for the ambient temperature.

In yet another embodiment processor 201 or the storage device may include a plurality of stored thresholds. The stored thresholds may be grouped into sets or schedules. In one form each set or schedule may correspond to a different season or a different set of ambient conditions. For example one set of threshold values relates to summer, another set of threshold values relates to winter and so on. The different seasonal threshold values are calculated to have taken into account the differing ambient conditions and ambient temperatures. In another embodiment sets and schedules of thresholds may be transmitted to the processor by the external administrator. The external administrator may calculate various thresholds for various seasons or ambient conditions. The external administrator may transmit different sets of thresholds for different seasons. In an alternate form the external administrator 11 may transmit a set of thresholds for different ambient temperatures measured by the sensors 202 or by a further sensor module measuring ambient temperature.

In another embodiment the temperature signals, and information regarding which thresholds are exceeded can be recorded by the processor and stored on the storage device 203. The stored information can be further processed by the processor 201, based on stored instructions in the storage device 203 or in the processor 201. The processor may calculate or derive statistical information from the stored information, such as average values, maximum, minimum values, medians and so on. The stored information or statistical information can be transmitted to the external administrator 11. The processor 201 may be adapted to generate a trigger signal or transmit an alarm signal based on the stored information or the statistical information derived from the stored information. The stored information may be processed or monitored to determine if the meter is operating correctly.

In another embodiment the temperature signal information and the information regarding which thresholds were exceeded is transmitted to an external administrator 11. The external administrator 11 may then process the information to derive statistical information such as averages, medians, maximum and minimum values and so on. The external administrator may further store the information. The historical information and new information stored may be monitored to determine if the meter is operating correctly or not. One or more actions may be remotely triggered by the external administrator 11 if a fault is detected based on the recorded information or the statistical information. For example if an abnormally high average temperature reading is received or the average temperature is increasing a trigger signal can be remotely sent to trigger an action such as activating a load control relay 204.

In another embodiment the apparatus 200 may include additional sensors that measure additional values besides temperature. Some examples are current passing through the mains wiring, voltage drop across the mains wiring in the meter or even the resistance of the mains wiring. These sensors may be part of the existing sensors 202 or may be additional sensors positioned about the meter 1.

The apparatus may comprise at least one or more thresholds that relate to current or voltage drop. The new readings of current or voltage drop may be compared to thresholds relating to current or voltage drop levels. If the current usage or the voltage drop exceeds one or more thresholds the processor 201 may generate a trigger signal to trigger an action. The trigger signal may trigger actions such as the generation of an alarm signal or the activation of a load control relay 204 or a mains breaker 206.

In one embodiment the processor 201 may check the current usage and the temperature reading against separate current and temperature thresholds. The current and temperature are related. In general the temperature within or about the meter is proportional to the square of the current through the wires. The processor 201 may be arranged to check both the current against a current threshold and the temperature against a temperature threshold. In one form if the either the current or the temperature exceed their respective thresholds, the processor may generate a trigger signal that is sent to an action device to trigger an action. In another form if both the current threshold and the temperature threshold is exceeded the processor may generate a trigger signal. In a further form the processor 201 is adapted to check the temperature and current against multiple current and multiple temperature thresholds. Each of the thresholds may have an associated action.

In yet another embodiment the processor 201 may include a relationship between current and temperature. This relationship may be defined mathematically and stored within the processor 201 or the storage device 203. The processor 201 may be arranged to determine temperature based on current measurement using the relationship between the temperature and current. The temperature threshold may be calculated using the relationship between current and temperature. For example if there is a current threshold A, the corresponding temperature threshold should be B based on the relationship between current and temperature within or about the meter 1. Therefore if a current A is measured and the measured temperature is C, which is greater than the expected temperature B, the processor 201 may generate a signal to trigger an action. In another example if the current is too high for the measured temperature then an action is triggered. In a further example if a measured current is much lower than an expected current for, a measured temperature an action is trigger. In another example if the measured temperature is much lower than the expected temperature for a given or measured current, an action may be triggered or at least the processor 201 generates a trigger signal. The specification refers to too low or too high. These too low and too high values are the threshold values and are either hard coded into the processor 201 or remotely transmitted. In another form the processor 201 may dynamically change the thresholds based on stored sets or schedules as described above.

The various embodiments of methods and apparatus described above are related to monitoring temperature or other parameters in or about a meter. These methods and apparatuses are advantageous because they monitor the operation of a meter and compare the operation with various thresholds that relate to potentially hazardous conditions within or about the meter. If one or more thresholds are exceeded then an action is taken to reduce any harmful effects to the meter. The method and apparatus described above provides a way to monitor the operation of an electric meter without physically opening the meter 1 to monitor what is happening.

In embodiments of the present invention, instantaneous temperature values may be utilised to determine meter conditions, or, temperature gradients may be used to determine meter conditions, or they may be used together in any combination.

In further embodiments, the temperature values used to determine a condition of a meter may relate to a temperature profile.

In embodiments of the present invention, the thresholds used to monitor the condition of a meter can relate to instantaneous temperature or temperature gradient or temperature profile or any combination thereof. Multiple thresholds can be used and exceeding a threshold has an associated action. The thresholds may relate to a particular condition of a meter.

The above described embodiments disclose the use of temperature as a fault parameter for electricity meters. The invention is not limited to this. Embodiments may be implemented to monitor the condition of other utility meters such as gas meters, water meters or any other utility meter. Temperature as a fault condition may be particularly useful for other utility meters, as there do not have many other parameters available for fault monitoring (such as voltage and current).

The present invention is not limited to the “action devices” discussed with regard to the above embodiment. Any action may be taken in response to a determined temperature value. In an embodiment, the action may be merely providing information so that an assessment may be made of the condition associated with the meter.

The invention is not limited to the electricity meter described with reference to FIG. 1. Embodiments may be applied with any electricity meter. The electricity meter may not require a remote comms device in some embodiments. Action may be taken in a “stand alone” meter in response to temperature, for example.

In the above embodiment, there are a plurality of temperature sensors. The invention is not limited to this. One sensor only may be applied in some embodiments.

The above embodiment is mainly concerned with increasing temperature. The invention is not limited to this. Cold temperatures could also indicate potential faults and require action.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method of monitoring temperature in a utility meter comprising the steps of:
obtaining one or more temperature signals from which a temperature value can be derived and deriving one or more temperature gradient values;
determining whether the one or more temperature gradient values exceed one or more threshold values; and if so
providing a trigger signal arranged to trigger an action.

2. The method as claimed in claim 1 comprising the step of processing the one or more temperature signals to determine one or more instantaneous temperature values.

3. The method as claimed in claim 2, comprising deriving the one or more temperature gradient values from changes in the one or more instantaneous temperature values during a predetermined time period.

4. (canceled)

5. (canceled)

6. The method as claimed in claim 1, wherein each threshold value is associated with at least one corresponding trigger value, such that when a threshold value is exceeded the trigger signal includes the at least one corresponding trigger value.

7. (canceled)

8. The method as claimed in claim 1, wherein the method comprises the step of checking whether a derived instantaneous temperature has exceeded a minimum threshold.

9. (canceled)

10. The method as claimed in claim 8, the method comprising the additional step of checking if the temperature gradient has exceeded a detection threshold, if the instantaneous temperature has exceeded the minimum threshold.

11. The method as claimed in claim 10 comprising the additional step of activating at least one load control breaker if the detection threshold has been exceeded.

12. The method as claimed in claim 8 comprising the additional step of checking if the instantaneous temperature has exceeded a maximum threshold, if the minimum threshold and the detection threshold have been exceeded.

13. The method as claimed in claim 12, wherein the method comprising the additional step of activating a mains breaker if the maximum threshold has been exceeded.

14. (canceled)

15. (canceled)

16. (canceled)

17. (canceled)

18. (canceled)

19. (canceled)

20. An apparatus for monitoring temperature in a utility meter comprising:
one or more sensors arranged to collect a temperature signal;
a processor arranged to receive one or more temperature signals from the one or more sensors, derive one or more temperature gradient values, determine whether the one or more temperature gradient values exceed one or more thresholds, and send a trigger signal to an action device to perform an action; and
at least one action device arranged to receive a trigger signal from the processor and execute an action.

21. The apparatus as claimed in claim 20, wherein the processor is arranged to process the one or more temperature signals to determine one or more instantaneous temperature values.

22. The apparatus as claimed in claim 21, wherein the processor derives the one or more temperature gradient values from changes in the one or more instantaneous temperature values during a predetermined time period.

23. (canceled)

24. (canceled)

25. The apparatus as claimed in claim 20, wherein each threshold value is associated with at least one corresponding trigger value, such that when the threshold value is exceeded the trigger signal sent to the action device includes the at least one corresponding trigger value to trigger the at least one action device.

26. (canceled)

27. The apparatus as claimed in claim 20, wherein the processor checks whether a derived instantaneous temperature has exceeded a minimum threshold.

28. (canceled)

29. The apparatus as claimed in claim 27, wherein the processor is arranged to check if the temperature gradient has exceeded a detection threshold, if the instantaneous temperature has exceeded the minimum threshold.

30. The apparatus as claimed in claim 29, wherein the processor is arranged to trigger at least one load control breaker if the detection threshold has been exceeded.

31. The apparatus as claimed in claim 27, wherein the processor is arranged to check if the instantaneous temperature has exceeded a maximum threshold, if the minimum threshold and the detection threshold have been exceeded.

32. The apparatus as claimed in claim 31, wherein the processor is arranged to activate a mains breaker if the maximum threshold has been exceeded.

33. (canceled)

34. (canceled)

35. (canceled)

36. (canceled)

37. (canceled)

38. (canceled)

39. (canceled)

40. A method of monitoring the condition of a utility meter comprising the steps of:
obtaining a temperature value associated with the meter;
determining whether the temperature value crosses a threshold; and
triggering an action if the threshold value is crossed;
wherein the temperature value is a temperature gradient.

41. (canceled)

42. (canceled)

43. (canceled)

44. An apparatus for monitoring the condition of a utility meter comprising:
a processor arranged to determine a temperature value associated with the meter;
the processor further arranged to determine whether the temperature value crosses a threshold value; and
the processor arranged to trigger an action device if a threshold value is crossed;
wherein the temperature value is a temperature gradient.

45. (canceled)

46. (canceled)

47. (canceled)
